(19) United States
(12) Patent Application Publication
(10) Pub. No.: US 2025/0118387 A1
(43) Pub. Date: Apr. 10, 2025

(54) MEMORY INCLUDING ERROR CORRECTION CIRCUIT

(71) Applicant: SK hynix Inc., Gyeonggi-do (KR)

(72) Inventors: Mun Seon JANG, Gyeonggi-do (KR); Sang Uhn CHA, Gyeonggi-do (KR)

(21) Appl. No.: 18/525,856

(22) Filed: Dec. 1, 2023

(30) Foreign Application Priority Data
Oct. 5, 2023 (KR) 10-2023-0132159

(51) Int. Cl. G11C 29/42; G11C 29/10

(52) U.S. Cl. CPC G11C 29/42; G11C 29/10

(57) ABSTRACT

A memory may include a memory core, a syndrome generation circuit configured to generate a syndrome by using data that are read from the memory core and an error correction code (ECC), a first decoder configured to generate first error correction information by using a first decoding table and the syndrome, a second decoder configured to generate second error correction information by using a second decoding table different from the first decoding table and the syndrome, and an error correction circuit configured to correct an error of the read data by using the first error correction information and the second error correction information.

### CROSS-REFERENCE TO RELATED APPLICATION

This application claims priority under 35 U.S.C. § 119 to Korean Patent Application No. 10-2023-0132159 filed on Oct. 5, 2023, which is incorporated herein by reference in its entirety.

### BACKGROUND

### 1. Technical Field

Embodiments of the present disclosure relate to a memory and, particularly, to an error correction in a memory.

### 2. Related Art

At the early stage of the semiconductor memory industry, multiple original good dies each not having any defective memory cells in a memory that has passed a semiconductor manufacturing process are distributed on a wafer. However, as the capacity of a memory is gradually increased, it becomes difficult to manufacture a memory not having any defective memory cells. Today, it may be said that there is no probability that such a memory will be manufactured. As one expedient for overcoming such a situation, a method of repairing defective memory cells of a memory by using redundancy memory cells is used.

Furthermore, as another expedient, in a memory system, an error occurring in a memory cell and an error occurring as data are transmitted in a read and write process of a memory system are corrected by using an error correction circuit (ECC circuit) that corrects an error.

### SUMMARY

In an embodiment of the present disclosure, a memory may include a memory core; a syndrome generation circuit configured to generate a syndrome based on data and an error correction code (ECC), which are read from the memory core; a first decoder configured to generate first error correction information based on a first decoding table and the syndrome; a second decoder configured to generate second error correction information based on the syndrome and a second decoding table different from the first decoding table; and an error correction circuit configured to correct an error of the read data based on the first error correction information and the second error correction information.

In an embodiment of the present disclosure, a memory may include a memory core; a syndrome generation circuit configured to generate a syndrome based on data and an error correction code (ECC), which are read from the memory core; a single error decoder configured to generate random 1-bit error correction information based on the syndrome and a decoding table identical with a check matrix that is used to generate the syndrome; a first neighboring 2-bit error decoder configured to generate first neighboring 2-bit error correction information based on the first decoding table and the syndrome; a second neighboring 2-bit error decoder configured to generate second neighboring 2-bit error correction information based on the syndrome and a second decoding table different from the first decoding table; and an error correction circuit configured to correct a random 1-bit error of the read data based on the random 1-bit error correction information and to correct a neighboring 2-bit error of the read data based on the first neighboring 2-bit error correction information and the second neighboring 2-bit error correction information.

These and other features and advantages of the invention will become apparent from the detailed description of embodiments of the present disclosure and the following figures.

### BRIEF DESCRIPTION OF THE DRAWINGS

FIG. 1 is a diagram illustrating an error correction code (ECC) encoder and an ECC decoder according to an embodiment of the present disclosure.

FIG. 2 is a diagram illustrating an example of a check matrix that is used by the ECC encoder and the ECC decoder.

FIG. 3 is an equation illustrating a process of generating an ECC of the ECC encoder.

FIG. 4 is a diagram illustrating the results that the ECC encoder 110 has generated an ECC (0, 1, 1, 0) for data DATA (1, 1, 0, 0, 1, 0, 1, 0) by using the check matrix of FIG. 2.

FIG. 5 is a diagram illustrating a process of generating, by the ECC decoder, a syndrome for error corrections.

FIG. 6 is a diagram illustrating how the ECC decoder generates a syndrome when data do not include an error.

FIG. 7 is a diagram illustrating how the ECC decoder generates a syndrome when the data include an error.

FIG. 8 is a diagram illustrating a configuration of a memory according to an embodiment of the present disclosure.

FIGS. 9A to 9D are diagrams each illustrating a form in which 8-bit data are stored in a cell area of FIG. 8.

FIG. 10 is a diagram illustrating a configuration of an ECC block of FIG. 8 according to an embodiment of the present disclosure.

FIG. 11 is a diagram illustrating a 10×32 check matrix that is used by a check matrix operation circuit.

FIG. 12 is a diagram illustrating an operation for generating ECC of the check matrix operation circuit.

FIG. 13 is a diagram illustrating an operation that is performed by the check matrix operation circuit after the start of a decoding operation.

FIG. 14 is a diagram illustrating an operation of a syndrome generation circuit.

FIG. 15 is a diagram illustrating a decoding table that is used by a single error decoder.

FIG. 16 is a diagram illustrating a decoding table that is used by a first neighboring 2-bit error decoder.

FIG. 17 is a diagram illustrating a decoding table that is used by a second neighboring 2-bit error decoder.

### DETAILED DESCRIPTION

Hereinafter, embodiments according to the technical spirit of the present disclosure are described with reference to the accompanying drawings.

Embodiments of the present disclosure may provide a technology for improving the efficiency of the correction of an error in a memory.

According to embodiments of the present disclosure, the efficiency of the correction of an error in the memory can be improved.

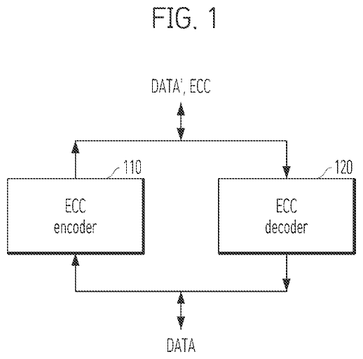

FIG. 1 is a diagram illustrating an error correction code (ECC) encoder 110 and an ECC decoder 120 according to an embodiment of the present disclosure.

The ECC encoder 110 may generate an ECC by using data DATA that are received from the outside of a memory (e.g., received from a memory controller) after the start of a write operation. That is, the ECC encoder 110 may generate the ECC for correcting an error of the data DATA by encoding the data DATA. In a process of generating the ECC, the data DATA that is an encoding target may also be called a message. After the start of the write operation, the ECC is only generated, and an operation of correcting the error is not performed. Accordingly, the data DATA that are input to the ECC encoder 110 and data DATA′ that are output by the ECC encoder 110 may be the same.

After the start of the write operation, the data DATA′ and the ECC may be stored in a memory core (not illustrated). Furthermore, after the start of a read operation, the data DATA′ and the ECC may be read from the memory core and transmitted to the ECC decoder 120.

After the start of the read operation, the ECC decoder 120 may correct an error of the data DATA′ by using the ECC. In this case, correcting the error may mean that an error of the data DATA′ is detected by using the ECC and is corrected when the error is detected. The data DATA having the error corrected by the ECC decoder 120 may be output to the outside of the memory (e.g., transmitted to the memory controller).

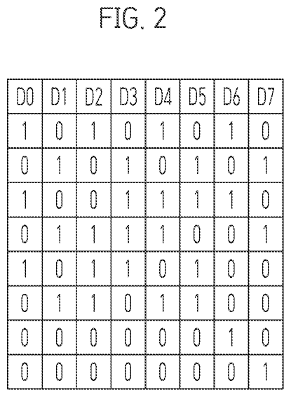

FIG. 2 is a diagram illustrating an example of a check matrix that is used by the ECC encoder 110 and the ECC decoder 120. In this case, for convenience of description, the data DATA include 8 bits D0 to D7 and an ECC includes 8 bits E0 to E7.

The check matrix may consist of a matrix of (the number of bits of the ECC)×(the number of bits of the data). In this case, the check matrix may have an 8×8 matrix because the ECC includes the 8 bits and the data include 8 bits. Each component of the check matrix may have a value of 1 or 0.

Column vectors of the check matrix may correspond to the bits D0 to D7 of the data DATA, respectively. For example, the 8 column vectors may correspond to the bits D0 to D7 of the data DATA, respectively. It may be seen that in FIG. 2, D1 corresponds to a column vector having a value of “01010100”.

How an ECC is generated by using the check matrix is described. Each of the bits E0 to E7 of the ECC may be generated by multiplying each of the bits D0 to D7 of the data DATA by a corresponding column vector and adding the results of the multiplication in a transverse direction. For example, the bits E0 to E7 of the ECC may be generated as in Equations 1 to 8, respectively.

$$[ Equation 1 ]$$

$$1 D 0 + 0 D 1 + 1 D 2 + 0 D 3 + 1 D 4 + 0 D 5 + 1 D 6 + 0 D 7 = E 0$$

$$[ Equation 2 ]$$

$$0 D 0 + 1 D 1 + 0 D 2 + 1 D 3 + 0 D 4 + 1 D 5 + 0 D 6 + 1 D 7 = E 1$$

$$[ Equation 3 ]$$

$$1 D 0 + 0 D 1 + 0 D 2 + 1 D 3 + 1 D 4 + 1 D 5 + 1 D 6 + 0 D 7 = E 2$$

$$[ Equation 4 ]$$

$$0 D 0 + 1 D 1 + 1 D 2 + 1 D 3 + 1 D 4 + 0 D 5 + 0 D 6 + 1 D 7 = E 3$$

$$[ Equation 5 ]$$

$$1 D 0 + 0 D 1 + 1 D 2 + 1 D 3 + 0 D 4 + 1 D 5 + 0 D 6 + 0 D 7 = E 4$$

$$[ Equation 6 ]$$

$$0 D 0 + 1 D 1 + 1 D 2 + 0 D 3 + 1 D 4 + 1 D 5 + 0 D 6 + 0 D 7 = E 5$$

$$[ Equation 7 ]$$

$$0 D 0 + 0 D 1 + 0 D 2 + 0 D 3 + 0 D 4 + 0 D 5 + 1 D 6 + 0 D 7 = E 6$$

$$[ Equation 8 ]$$

$$0 D 0 + 0 D 1 + 0 D 2 + 0 D 3 + 0 D 4 + 0 D 5 + 0 D 6 + 1 D 7 = E 7$$

For reference, in the aforementioned equations and the following description, an addition means exclusive OR. Accordingly, the addition may be performed in a way that the results of the addition are 0 when the number of 1s is an even number and are 1 when the number of 1s is an odd number. For example, 1+1+0+1=1, and 0+1+1+0=0.

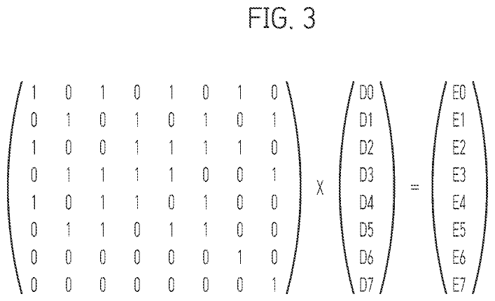

Equations 1 to 8 may be represented as in FIG. 3 in the form of a matrix product. Referring to FIG. 3, it may be seen that the 8-bit ECC (ECC=E0 to E7) is generated by performing a matrix product on the check matrix, that is, an 8×8 matrix, and the data (DATA=D0 to D7) having an 8×1 matrix.

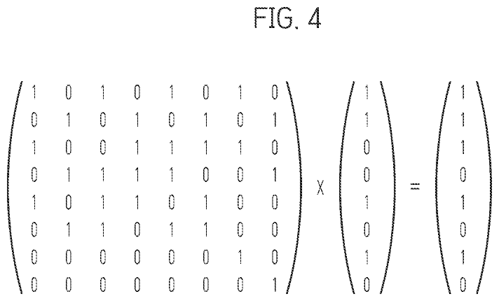

FIG. 4 is a diagram illustrating the results that the ECC encoder 110 has generated an ECC (1, 1, 1, 0, 1, 0, 1, 0) for data DATA (1, 1, 0, 0, 1, 0, 1, 0) by using the check matrix of FIG. 2.

Referring to FIG. 4, it may be seen that an ECC (1, 1, 1, 0, 1, 0, 1, 0) is generated by performing a matrix product on the check matrix, that is, the 8×8 matrix, and data DATA (1, 1, 0, 0, 1, 0, 1, 0), that is, an 8×1 matrix.

It may be seen that the results of the matrix product operation illustrated in FIG. 4 are the same as results obtained by putting the data (1, 1, 0, 0, 1, 0, 1, 0) into Equations 1 to 8 as below.

$$1 * 1 + 0 * 1 + 1 * 0 + 0 * 0 + 1 * 1 + 0 * 0 + 1 * 1 + 0 * 0 = 1$$

$$0 * 1 + 1 * 1 + 0 * 0 + 1 * 0 + 0 * 1 + 1 * 0 + 0 * 1 + 1 * 0 = 1$$

$$1 * 1 + 0 * 1 + 0 * 0 + 1 * 0 + 1 * 1 + 0 * 1 + 1 * 1 + 0 * 0 = 1$$

$$0 * 1 + 1 * 1 + 1 * 0 + 1 * 0 + 1 * 1 + 0 * 0 + 0 * 1 + 1 * 0 = 0$$

$$1 * 1 + 0 * 1 + 1 * 0 + 1 * 0 + 0 * 1 + 1 * 0 + 0 * 1 + 0 * 0 = 1$$

$$0 * 1 + 1 * 1 + 1 * 0 + 0 * 0 + 1 * 1 + 1 * 0 + 0 * 1 + 0 * 0 = 0$$

$$0 * 1 + 0 * 1 + 0 * 0 + 0 * 0 + 0 * 1 + 0 * 0 + 1 * 1 + 0 * 0 = 1$$

$$0 * 1 + 0 * 1 + 0 * 0 + 0 * 0 + 0 * 1 + 0 * 0 + 0 * 1 + 1 * 0 = 0$$

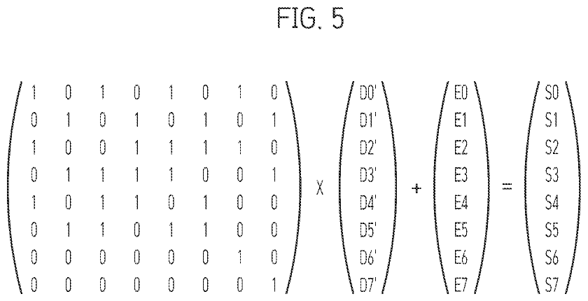

FIG. 5 is a diagram illustrating a process of generating, by the ECC decoder 120, a syndrome S0 to S7 for error corrections.

Referring to FIG. 5, the ECC decoder 120 may generate the syndrome S0 to S7 by performing a matrix product on the check matrix of FIG. 2, which is the same as the check matrix that is used by the ECC encoder 110, and read data (DATA′=D0′ to D7′) and adding a read ECC (ECC=E0 to E7) to the results of the matrix product.

FIG. 5 may be represented in the following equation.

$$1 * D {0}^{′} + 0 * D {1}^{′} + 1 * D {2}^{′} + 0 * D {3}^{′} + 1 * D {4}^{′} + 0 * D {5}^{′} + 1 * D {6}^{′} + 0 * D {7}^{′} + E 0 = S 0$$

$$0 * D {0}^{′} + 1 * D {1}^{′} + 0 * D {2}^{′} + 1 * D {3}^{′} + 0 * D {4}^{′} + 1 * D {5}^{′} + 0 * D {6}^{′} + 1 * D {7}^{′} + E 1 = S 1$$

$$1 * D {0}^{′} + 0 * D {1}^{′} + 0 * D {2}^{′} + 1 * D {3}^{′} + 1 * D {4}^{′} + 1 * D {5}^{′} + 1 * D {6}^{′} + 0 * D {7}^{′} + E 2 = S 2$$

$$0 * D {0}^{′} + 1 * D {1}^{′} + 1 * D {2}^{′} + 1 * D {3}^{′} + 1 * D {4}^{′} + 0 * D {5}^{′} + 0 * D {6}^{′} + 1 * D {7}^{′} + E 3 = S 3$$

$$1 * D {0}^{′} + 0 * D {1}^{′} + 1 * D {2}^{′} + 1 * D {3}^{′} + 0 * D {4}^{′} + 1 * D {5}^{′} + 0 * D {6}^{′} + 0 * D {7}^{′} + E 4 = S 4$$

$$0 * D {0}^{′} + 1 * D {1}^{′} + 1 * D {2}^{′} + 0 * D {3}^{′} + 1 * D {4}^{′} + 1 * D {5}^{′} + 0 * D {6}^{′} + 0 * D {7}^{′} + E 5 = S 5$$

$$0 * D {0}^{′} + 0 * D {1}^{′} + 0 * D {2}^{′} + 0 * D {3}^{′} + 0 * D {4}^{′} + 0 * D {5}^{′} + 1 * D {6}^{′} + 0 * D {7}^{′} + E 6 = S 6$$

$$0 * D {0}^{′} + 0 * D {1}^{′} + 0 * D {2}^{′} + 0 * D {3}^{′} + 0 * D {4}^{′} + 0 * D {5}^{′} + 0 * D {6}^{′} + 1 * D {7}^{′} + E 7 = S 7$$

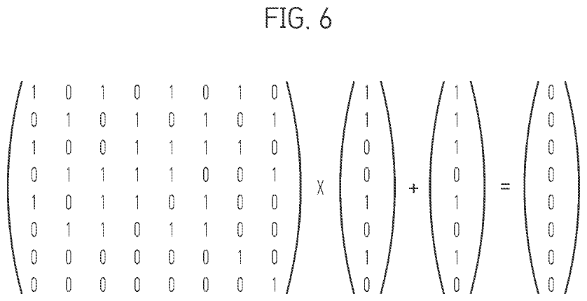

FIG. 6 is a diagram illustrating how the ECC decoder 120 generates a syndrome S0 to S7 when data DATA′ do not include an error. The data (1, 1, 0, 0, 1, 0, 1, 0) and the ECC (1, 1, 1, 0, 1, 0, 1, 0) illustrated in FIG. 4 have been stored in the memory core and then read again without any change.

Referring to FIG. 6, it may be seen that the values of the syndrome S0 to S7 are generated as (0, 0, 0, 0, 0, 0, 0, 0) by performing a matrix product on the check matrix of FIG. 2 and read data DATA′ (1, 1, 0, 0, 1, 0, 1, 0) and adding a read ECC (1, 1, 1, 0, 1, 0, 1, 0) to the results of the matrix product.

FIG. 6 may be represented in the following equation.

$$1 * 1 + 0 * 1 + 1 * 0 + 0 * 0 + 1 * 1 + 0 * 0 + 1 * 1 + 0 * 0 + 1 = 0$$

$$0 * 1 + 1 * 1 + 0 * 0 + 1 * 0 + 0 * 1 + 1 * 0 + 0 * 1 + 1 * 0 + 1 = 0$$

$$1 * 1 + 0 * 1 + 0 * 0 + 1 * 0 + 1 * 1 + 0 * 1 + 1 * 1 + 0 * 0 + 1 = 0$$

$$0 * 1 + 1 * 1 + 1 * 0 + 1 * 0 + 1 * 1 + 0 * 0 + 0 * 1 + 1 * 0 + 0 = 0$$

$$1 * 1 + 0 * 1 + 1 * 0 + 1 * 0 + 0 * 1 + 1 * 0 + 0 * 1 + 0 * 0 + 1 = 0$$

$$0 * 1 + 1 * 1 + 1 * 0 + 0 * 0 + 1 * 1 + 1 * 0 + 0 * 1 + 0 * 0 + 0 = 0$$

$$0 * 1 + 0 * 1 + 0 * 0 + 0 * 0 + 0 * 1 + 0 * 0 + 1 * 1 + 0 * 0 + 1 = 0$$

$$0 * 1 + 0 * 1 + 0 * 0 + 0 * 0 + 0 * 1 + 0 * 0 + 0 * 1 + 1 * 0 + 0 = 0$$

When all values of the syndrome S0 to S7 are 0, it may indicate that the read data DATA′ do not include an error. When all values of the syndrome are 0, the ECC decoder 120 may determine that the data DATA′ do not include an error and output the data DATA′ without any change (DATA′=DATA).

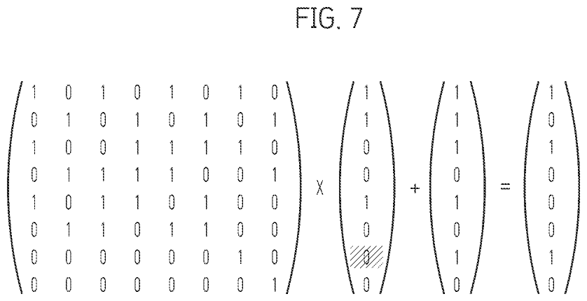

FIG. 7 is a diagram illustrating how the ECC decoder 120 generates a syndrome S0 to S7 when data DATA′ include an error. After the data DATA (1, 1, 0, 0, 1, 0, 1, 0) and the ECC (1, 1, 1, 0, 1, 0, 1, 0) illustrated in FIG. 4 were stored in the memory core, data DATA′ have been read as (1, 1, 0, 0, 1, 0, 0, 0) and an ECC has been read as (1, 1, 1, 0, 1, 0, 1, 0) and input to the ECC decoder 120 because an error occurs in a bit D6 of the data.

Referring to FIG. 7, it may be seen that the values of the syndrome S0 to S7 are generated as (1, 0, 1, 0, 0, 0, 1, 0) by performing a matrix product on the check matrix of FIG. 2 and read data DATA′ (1, 1, 0, 0, 1, 0, 0, 0) and adding a read ECC (1, 1, 1, 0, 1, 0, 1, 0) to the results of the matrix product.

FIG. 7 may be represented in the following equation.

$$1 * 1 + 0 * 1 + 1 * 0 + 0 * 0 + 1 * 1 + 0 * 0 + 1 * 0 + 0 * 0 + 1 = 1$$

$$0 * 1 + 1 * 1 + 0 * 0 + 1 * 0 + 0 * 1 + 1 * 0 + 0 * 0 + 1 * 0 + 1 = 0$$

$$1 * 1 + 0 * 1 + 0 * 0 + 1 * 0 + 1 * 1 + 1 * 0 + 1 * 0 + 0 * 0 + 1 = 1$$

$$0 * 1 + 1 * 1 + 1 * 0 + 1 * 0 + 1 * 1 + 0 * 0 + 0 * 0 + 1 * 0 + 0 = 0$$

$$1 * 1 + 0 * 1 + 1 * 0 + 1 * 0 + 0 * 1 + 1 * 0 + 0 * 0 + 0 * 0 + 1 = 0$$

$$0 * 1 + 1 * 1 + 1 * 0 + 0 * 0 + 1 * 1 + 1 * 0 + 0 * 0 + 0 * 0 + 0 = 0$$

$$0 * 1 + 0 * 1 + 0 * 0 + 0 * 0 + 0 * 1 + 0 * 0 + 1 * 0 + 0 * 0 + 1 = 0$$

$$0 * 1 + 0 * 1 + 0 * 0 + 0 * 0 + 0 * 1 + 0 * 0 + 0 * 0 + 1 * 0 + 0 = 0$$

Each of the values (1, 0, 1, 0, 0, 0, 1, 0) of the syndrome S0 to S7 may indicate the location of an error. A column vector having the values of 1, 0, 1, 0, 0, 0, 1, 0, among the column vectors of the check matrix of FIG. 2, may be a column vector corresponding to D6. Accordingly, the ECC decoder 120 may determine that D6 includes an error and may correct the error by inverting 0 in D6 into 1. By such an error correction, data DATA that are output by the ECC decoder 120 may become (0, 1, 0, 0, 1, 0, 1, 0). That is, the error of the data DATA′ that have been input to the ECC decoder 120 may be corrected, and the data DATA having the error corrected may be generated.

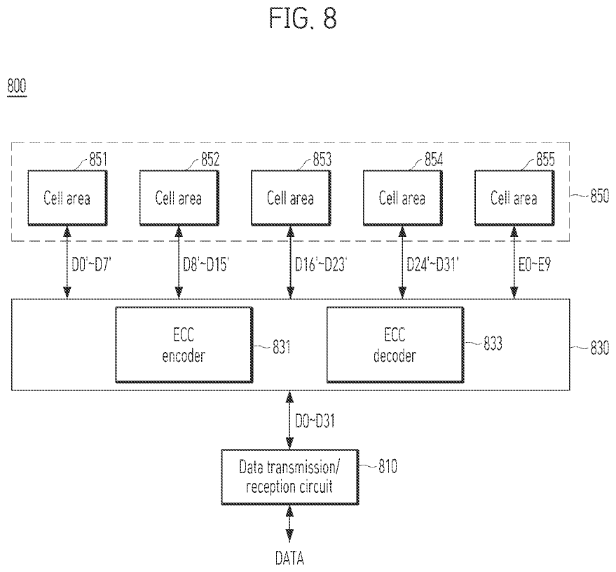

FIG. 8 is a diagram illustrating a configuration a memory 800 according to an embodiment of the present disclosure.

Referring to FIG. 8, the memory 800 may include a data transmission/reception circuit 810, an ECC block 830, and a memory core 850.

The data transmission/reception circuit 810 may transmit and receive data DATA. The data transmission/reception circuit 810 may receive data DATA that are transmitted by a memory controller after the start of a write operation, and may transmit data DATA to the memory controller after the start of a read operation. In this case, it has been illustrated that the number of bits of data DATA that are transmitted/received by the data transmission/reception circuit 810 after the start of one write and read operation is 32 bits D0 to D31.

The ECC block 830 may include an ECC encoder 831 and an ECC decoder 833. The ECC encoder 831 may generate a 10-bit ECC E0 to E9 by using 32-bit data D0 to D31 that are received through the data transmission/reception circuit 810 after the start of a write operation. After the start of the write operation, the ECC E0 to E9 is only generated by the ECC encoder 831, and an error correction operation is not performed. Accordingly, after the start of the write operation, the data D0 to D31 that are input to the ECC block 830 and data D0′ to D31′ that are output by the ECC block 830 may be the same.

The ECC decoder 833 may correct an error of the data D0′ to D31′ that are transmitted by the memory core 850, by using the ECC E0 to E9 that is transmitted by the memory core 850. In this case, correcting the error may mean that an error of the data D0′ to D31′ is detected by using the ECC E0 to E9 and is corrected when the error is detected. The data D0 to D31 having the error corrected by the ECC decoder 833 may be transmitted to the memory controller by the data transmission/reception circuit 810. The ECC encoder 831 and the ECC decoder 833 may share some components in order to reduce the area of a circuit.

The memory core 850 may include multiple cell areas 851 to 855. Each of the cell areas 851 to 854 may store 8-bit data for each write operation. The cell area 855 may store 10-bit data for each write operation. For example, the data D0′ to D7′ may be stored in the cell area 851, and the data D8′ to D15′ may be stored in the cell area 852. Furthermore, the ECC E0 to E9 may be stored in the cell area 855.

FIG. 8 has illustrated that the 32-bit data D0 to D31 are input to and output from the memory 800 after the start of one write and read operation and the 10-bit ECC E0 to E9 is used, but this is merely an example. The number of bits of the data and the number of bits of the ECC may be different from those illustrated in the example of FIG. 8.

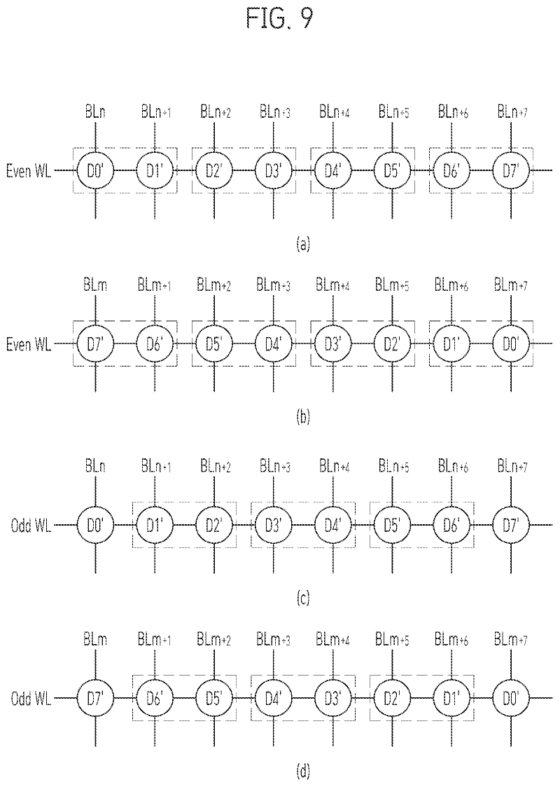

FIGS. 9A to 9D are diagrams each illustrating a form in which 8-bit data D0′ to D7′ are stored in a cell area 851 of FIG. 8.

The cell area 851 may include multiple rows and multiple columns, and may include multiple memory cells that are formed at the intersections of the rows and the columns, respectively. After the start of a write operation, one of the multiple rows (or word lines) may be selected by a row address, 8 columns of the multiple columns (or bit lines) may be selected by a column address, and the data D0′ to D7′ may be stored in 8 memory cells of the selected rows and the selected columns.

FIG. 9A illustrates a form in which the data D0′ to D7′ are stored in the cell area 851 when the row address is an even number and the column address is an even number.

Referring to FIG. 9A, it may be seen that the 8-bit data D0′ to D7′ have been stored in 8 memory cells, respectively, which have been formed at the intersections of an even word line Even WL (means a word line that has been selected by the row address, that is, an even number) and 8 bit lines BLn to BLn+7 (mean 8 bit lines that have been selected by the column address, that is, an even number). In FIG. 9A, a dotted line is a line that binds memory cells having a high possibility that a storage node bridge failure may occur. For example, this may mean that there is a high possibility that a bridge may occur in the storage node of a memory cell in which the data D0′ are stored and the storage node of a memory cell in which the data D1′ are stored and there is a high possibility that a bridge may occur in the storage node of a memory cell in which the data D2′ are stored and the storage node of a memory cell in which the data D3′ are stored. That is, there may be a high possibility that errors may simultaneously occur in the data D0′ and the data D1′, and there may be a high possibility that errors may simultaneously occur in the data D2′ and the data D3′.

FIG. 9B illustrates a form in which the data D0′ to D7′ are stored in the cell area 851 when the row address is an even number and the column address is an odd number.

Referring to FIG. 9B, it may be seen that the 8-bit data D0′ to D7′ have been stored in 8 memory cells, respectively, which have been formed at the intersections of an even word line Even WL and 8 bit lines BLm to BLm+7 (mean 8 bit lines that have been selected by the column address, that is, an odd number). In the case of FIG. 9B, it may be seen that the data D0′ to D7′ are sequentially stored in the 8 memory cells in order of D7′, D6′, D5′, D4′, D3′, D2′, D1′, and D0′. In FIG. 9B, a dotted line is a line that binds memory cells having a high possibility that a storage node bridge failure may occur. It may be seen that in FIG. 9B, the data are stored in the memory cells in the order different from the order of FIG. 9A, but the data having a high possibility that errors may simultaneously occur are the same as those in FIG. 9A.

That is, in FIG. 9B, as in FIG. 9A, there is a high possibility that errors may simultaneously occur in the data D2′ and the data D3′, and there is a high possibility that errors may simultaneously occur in the data D0′ and the data D1′.

FIG. 9C illustrates a form in which the data D0′ to D7′ are stored in the cell area 851 when the row address is an odd number and the column address is an even number.

Referring to FIG. 9C, it may be seen that 8-bit data D0′ to D7′ have been stored in 8 memory cells, respectively, which have been formed at the intersections of an odd word line Odd WL (means a word line that has been selected by the row address, that is, an odd number) and 8 bit lines BLn to BLn+7. In the case of FIG. 9C, it may be seen that the data D0′ to D7′ are stored in the 8 memory cells in order of D0′, D1′, D2′, D3′, D4′, D5′, D6′, and D7′. In FIG. 9C, a dotted line is a line that binds memory cells having a high possibility that a storage node bridge failure may occur. In FIG. 9C, unlike in FIGS. 9A and 9B, it may be seen that there is a high possibility that errors may simultaneously occur in the data D1′ and the data D2′, there is a high possibility that errors may simultaneously occur in the data D3′ and the data D4′, and there is a high possibility that errors may simultaneously occur in the data D5′ and the data D6′. The reason for this may be that the memory cells of the even word line Even WL and the memory cells of the odd word line Odd WL have different arrangement forms.

That is, it may be seen that in the case of FIG. 9C and the cases of FIGS. 9A and 9B, pairs of 2-bit data having a high possibility that errors may simultaneously occur are different from each other.

FIG. 9D illustrates a form in which data D0′ to D7′ have been stored in the cell area 851 when the row address is an odd number and the column address is an odd number.

Referring to FIG. 9D, it may be seen that the 8-bit data D0′ to D7′ have been stored in 8 memory cells, respectively, which have been formed at the intersections of an odd word line Odd WL and 8 bit lines BLm to BLm+7. It may be seen that in the case of FIG. 9D, the data D0′ to D7′ have been stored in the 8 memory cells in order of D7′, D6′, D5′, D4′, D3′, D2′, D1′, and D0′. In FIG. 9D, a dotted line is a line that binds memory cells having a high possibility that a storage node bridge failure may occur. In FIG. 9D, unlike in FIGS. 9A and 9B and as in FIG. 9C, it may be seen that there is a high possibility that errors may simultaneously occur in the data D1′ and the data D2′, there is a high possibility that errors may simultaneously occur in the data D3′ and the data D4′, and there is a high possibility that errors may simultaneously occur in the data D5′ and the data D6′.

FIGS. 9A to 9D illustrate the forms in which the 8-bit data D0′ to D7′ are stored in the cell area 851. A form in which the 8-bit data D8′ to D15′ are stored in the cell area 852, a form in which the 8-bit data D16′ to D23′ are stored in the cell area 853, and a form in which the 8-bit data D24′ to D31′ are stored in the cell area 854 may be the same as the forms in which the 8-bit data D0′ to D7′ are stored in the cell area 851.

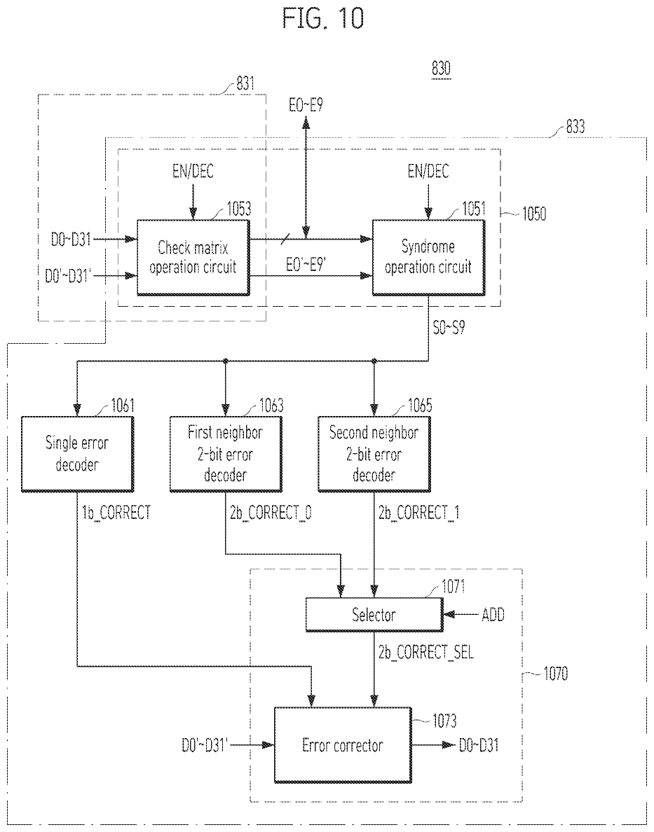

FIG. 10 is a diagram illustrating a configuration of the ECC block 830 of FIG. 8 according to an embodiment of the present disclosure.

Referring to FIG. 10, the ECC encoder 831 of the ECC block 830 may include a check matrix operation circuit 1053. The ECC decoder 833 of the ECC block 830 may include a syndrome generation circuit 1050, a single error decoder 1061, a first neighboring 2-bit error decoder 1063, a second neighboring 2-bit error decoder 1065, and an error correction circuit 1070. The syndrome generation circuit 1050 of the ECC decoder 833 may share the check matrix operation circuit 1053 along with the ECC encoder 831.

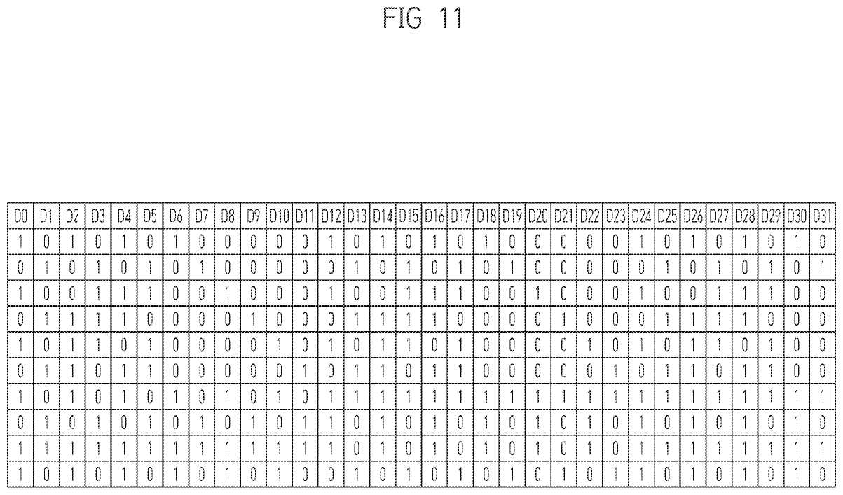

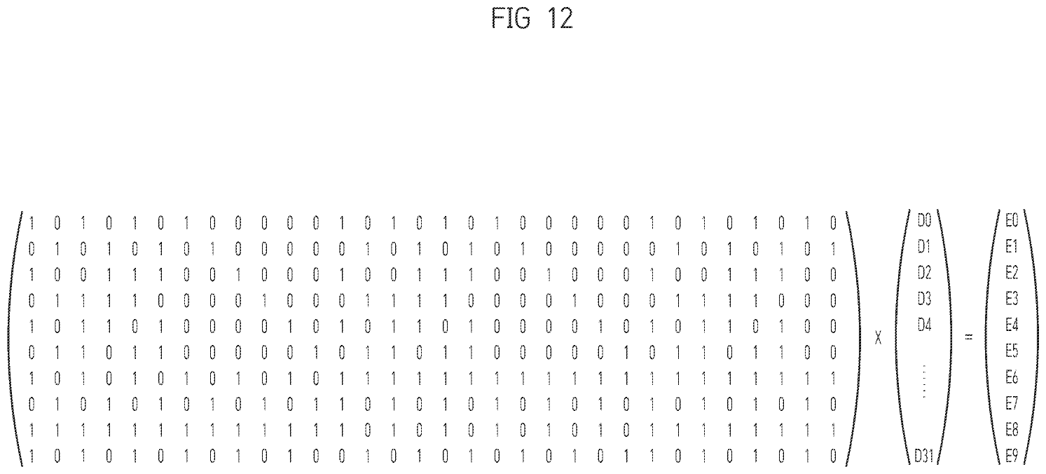

The check matrix operation circuit 1053 may be shared by the ECC encoder 831 and the ECC decoder 833, and thus may perform different operations after the start of an encoding operation and a decoding operation. The check matrix operation circuit 1053 may generate the ECC E0 to E9 by using a check matrix (FIG. 11) and the data D0 to D31 after the start of an encoding operation in which an encoding/decoding signal EN/DEC has been activated, that is, after the start of a write operation of generating the ECC E0 to E9. FIG. 11 illustrates a 10×32 check matrix that is used by the check matrix operation circuit 1053. FIG. 12 illustrates an operation for generating the ECC E0 to E9 of the check matrix operation circuit 1053. Referring to FIG. 12, it may be seen that after the start of an encoding operation, the check matrix operation circuit 1053 generates the ECC E0 to E9 by performing a matrix product operation on the 10×32 check matrix (FIG. 11) and 32×1 data D0 to D31.

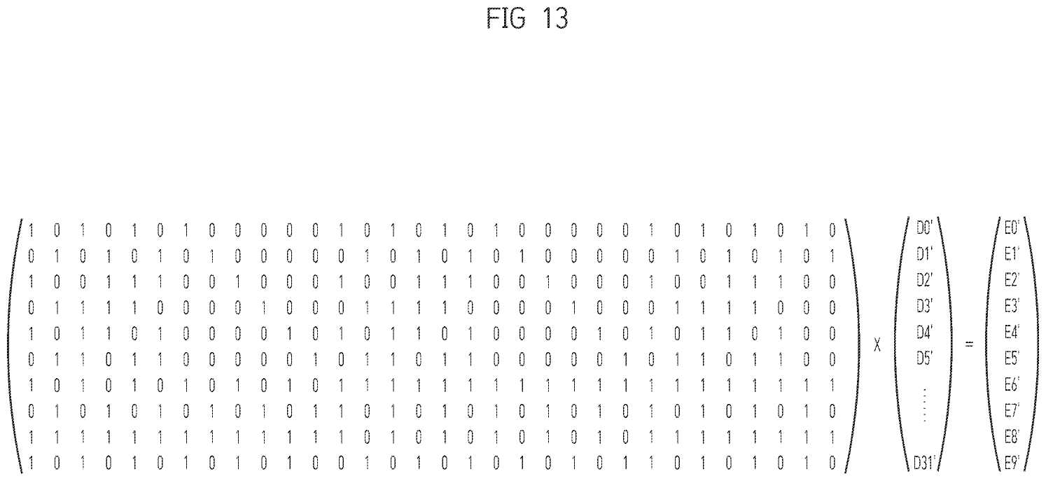

The check matrix operation circuit 1053 may generate operation results E0′ to E9′ by using the check matrix (FIG. 11) and the read data D0′ to D31′ from the memory core 850 after the start of a decoding operation in which the encoding/decoding signal EN/DEC has been deactivated, that is, after the start of a read operation. FIG. 13 illustrates an operation that is performed by the check matrix operation circuit 1053 after the start of a decoding operation. Referring to FIG. 13, it may be seen that the check matrix operation circuit 1053 generates the operation results E0′ to E9′ by performing a matrix product operation on the 10×32 check matrix (FIG. 11) and the 32×1 data D0′ to D31′ after the start of a decoding operation.

The check matrix operation circuit 1053 may generate the ECC E0 to E9 by receiving the write data D0 to D31 from the memory controller after the start of an encoding operation, and may generate the operation results E0′ to E9′ by receiving the read data D0′ to D31′ from the memory core 850 after the start of a decoding operation.

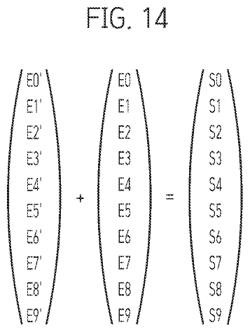

The syndrome generation circuit 1050 may include the check matrix operation circuit 1053 and a syndrome operation circuit 1051. The syndrome operation circuit 1051 may operate by being activated after the start of a decoding operation in which the encoding/decoding signal EN/DEC has been deactivated, and may be deactivated after the start of an encoding operation in which the encoding/decoding signal EN/DEC has been activated. The syndrome operation circuit 1050 may generate a syndrome S0 to S9 by adding the ECC E0 to E9, which has been read from the memory core 850, to the operation results E0′ to E9′ that have been generated by the check matrix operation circuit 1053 after the start of a decoding operation. FIG. 14 illustrates an operation of the syndrome generation circuit 1050. Referring to FIG. 14, it may be seen that the syndrome S0 to S9 is generated by adding the operation results E0′ to E9′ and the ECC E0 to E9.

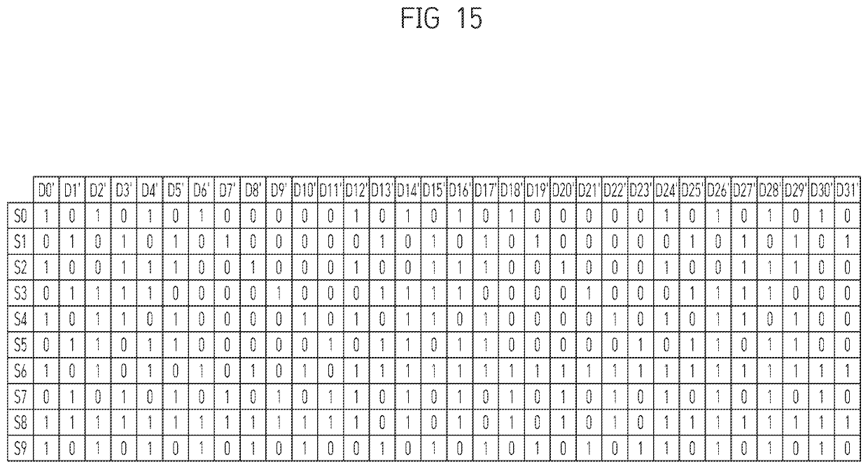

The single error decoder 1061 may generate random 1-bit error correction information 1b_CORRECT for correcting a random 1-bit error of the data D0′ to D31′ that have been read from the memory core 850, by decoding the syndrome S0 to S9. The single error decoder 1061 may use the same decoding table as the check matrix (FIG. 11) that is used by the check matrix operation circuit 1053. FIG. 15 illustrates the decoding table that is used by the single error decoder 1061. The single error decoder 1061 may generate the random 1-bit error correction information 1b_CORRECT indicating that data of a corresponding bit need to be corrected when the values of the syndrome S0 to S9 are identical with one of the column vectors of the decoding table in FIG. 15. For example, the single error decoder 1061 may generate the random 1-bit error correction information 1b_CORRECT indicating that an error is present in the data D10′ having the same column vector as (0, 0, 0, 0, 1, 0, 1, 0, 1, 1) when the values of the syndrome S0 to S9 are (0, 0, 0, 0, 1, 0, 1, 0, 1, 1), and may generate the random 1-bit error correction information 1b_CORRECT indicating that an error is present in the data D24′ having the same column vector as (1, 0, 1, 0, 1, 0, 1, 1, 1, 1) when the values of the syndrome are (1, 0, 1, 0, 1, 0, 1, 1, 1, 1).

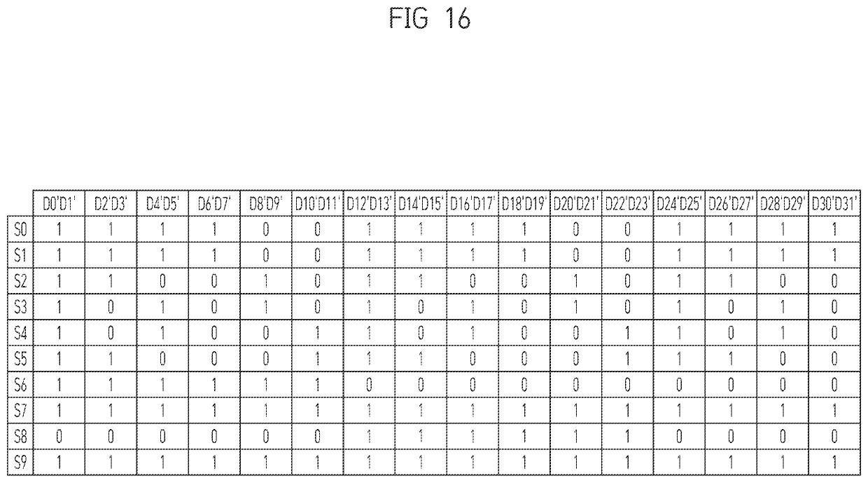

The first neighboring 2-bit error decoder 1063 may generate first neighboring 2-bit error information 2b_CORRECT_0 for correcting a neighboring 2-bit error of the data D0′ to D31′ that have been read from the memory core 850, by decoding the syndrome S0 to S9. The first neighboring 2-bit error decoder 1063 may be a decoder for generating the first neighboring 2-bit error information 2b_CORRECT_0 for correcting a neighboring 2-bit error if data have been stored in a form, such as the form illustrated in FIGS. 9A and 9B, and the neighboring 2-bit error occurs. For example, the first neighboring 2-bit error decoder 1063 may perform a decoding operation for correcting errors when the errors simultaneously occur in the data D0′ and the data D1′ having a high possibility that errors may simultaneously occur or the errors simultaneously occur in the data D2′ and the data D3′ having a high possibility that errors may simultaneously occur, in FIGS. 9A and 9B. FIG. 16 illustrates a decoding table that is used by the first neighboring 2-bit error decoder 1063. The decoding table of FIG. 16 may be a decoding table obtained by abbreviating the columns of the decoding table in FIG. 15 to 2:1. If data are stored in a form, such as the form illustrated in FIGS. 9A and 9B, the columns of the data may be abbreviated in a way to sum the columns of a data pair (e.g., D0′ and D1′) having a high possibility that errors may simultaneously occur. For example, a D0′D1′ column of the decoding table in FIG. 16 may be a column that has been abbreviated by summing the D0′ column and D1′ column of the decoding table in FIG. 15. Furthermore, a D12′D13′ column of the decoding table in FIG. 16 may be a column that has been abbreviated by summing the D12′ column and D13′ column of the decoding table in FIG. 15.

The first neighboring 2-bit error decoder 1063 may generate the first neighboring 2-bit error information 2b_CORRECT_0 indicating that errors are present in corresponding 2 bits when the values of the syndrome S0 to S9 are identical with one of the columns of the decoding table in FIG. 16. For example, if the values of the syndrome S0 to S9 are (1, 1, 0, 0, 0, 0, 1, 1, 0, 1), the column of (1, 1, 0, 0, 0, 0, 1, 1, 0, 1) is the same as a D6′D7′ column of the decoding table in FIG. 16. Accordingly, the first neighboring 2-bit error decoder 1063 may generate the first neighboring 2-bit error information 2b_CORRECT_0 indicating that errors are present in the data D6′ and the data D7′. Likewise, if the values of the syndrome S0 to S9 are (0, 0, 0, 0, 1, 1, 0, 1, 1, 1), the column of the values are the same as a D22′D23′ column of the decoding table in FIG. 16. Accordingly, the first neighboring 2-bit error decoder 1063 may generate the first neighboring 2-bit error information 2b_CORRECT_0 indicating that errors are present in the data D22′ and the data D23′.

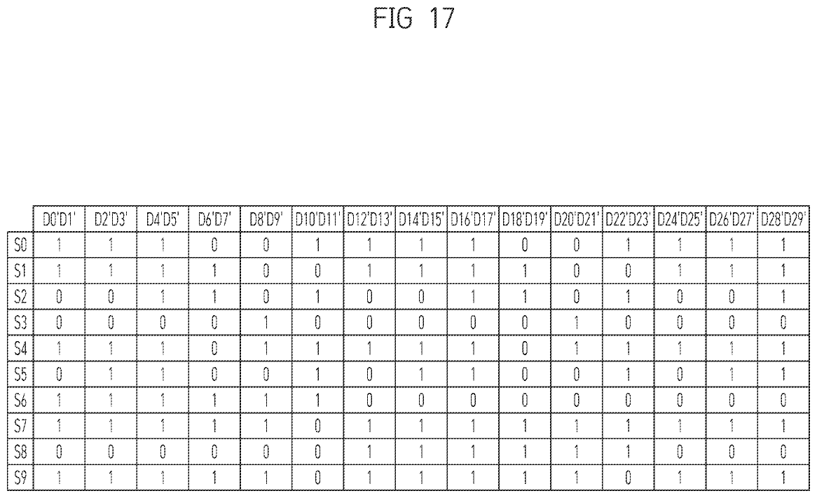

The second neighboring 2-bit error decoder 1065 may generate second neighboring 2-bit error information 2b_CORRECT_1 for correcting a neighboring 2-bit error of the data D0′ to D31′ that have been read from the memory core 850, by decoding the syndrome S0 to S9. The second neighboring 2-bit error decoder 1065 may be a decoder for generating the second neighboring 2-bit error information 2b_CORRECT_1 for correcting a neighboring 2-bit error if data have been stored in a form, such as the form illustrated in FIGS. 9C and 9D, and the neighboring 2-bit error occurs. For example, the second neighboring 2-bit error decoder 1065 may perform a decoding operation for correcting errors when the errors simultaneously occur in the data D1′ and the data D2′ having a high possibility that errors may simultaneously occur or errors simultaneously occur in the data D5′ and the data D6′ having a high possibility that errors may simultaneously occur, in FIGS. 9C and 9D. FIG. 17 illustrates a decoding table that is used by the second neighboring 2-bit error decoder 1065. The decoding table of FIG. 17 may be a decoding table obtained by abbreviating the columns of the decoding table in FIG. 15 to 2:1. If data are stored in a form, such as the form illustrated in FIGS. 9C and 9D, the columns of the data may be abbreviated in a way to sum the columns of a data pair (e.g., D1′ and D2′) having a high possibility that errors may simultaneously occur. For example, a D1′D2′ column of the decoding table in FIG. 17 may be a column that has been abbreviated by summing the D1′ column and D2′ column of the decoding table in FIG. 15. Furthermore, a D15′D16′ column of the decoding table in FIG. 17 may be a column that has been abbreviated by summing the D15′ column and D16′ column of the decoding table in FIG. 15.

The second neighboring 2-bit error decoder 1065 may generate the second neighboring 2-bit error information 2b_CORRECT_1 indicating that errors are present in corresponding 2 bits when the values of the syndrome S0 to S9 are identical with one of the columns of the decoding table in FIG. 17. For example, if the values of the syndrome S0 to S9 are (1, 1, 1, 0, 1, 1, 1, 1, 0, 1), the column of (1, 1, 1, 0, 1, 1, 1, 1, 0, 1) is the same as a D5′D6′ column of the decoding table in FIG. 17. Accordingly, the second neighboring 2-bit error decoder 1065 may generate the second neighboring 2-bit error information 2b_CORRECT_1 indicating that errors are present in the data D5′ and the data D6′. Likewise, if the values of the syndrome S0 to S9 are (1, 1, 0, 0, 1, 0, 0, 1, 0, 1), the column of (1, 1, 0, 0, 1, 0, 0, 1, 0, 1) is the same as a D25′D26′ column of the decoding table in FIG. 17. The second neighboring 2-bit error decoder 1065 may generate the second 2-bit neighboring error information 2b_CORRECT_1 indicating that errors are present in the data D25′ and the data D26′.

The error correction circuit 1070 may correct errors of the data D0′ to D31′ that have been read from the memory core 850, by using the error information 1b_CORRECT, 2b_CORRECT_0, and 2b_CORRECT_1 that have been generated by the decoders 1061, 1063, 1065, and 1067, respectively. The error correction circuit 1070 may include a selector 1071 and an error corrector 1073.

The selector 1071 may select one of the first neighboring 2-bit error information 2b_CORRECT_0 and the second neighboring 2-bit error information 2b_CORRECT_1. If the data D0′ to D31′ read from the memory core 850 have been stored in the memory core 850 in a form, such as the form illustrated in FIGS. 9A and 9B, the first neighboring 2-bit error information 2b_CORRECT_0 may be required to correct a neighboring 2-bit error. If the data D0′ to D31′ read from the memory core 850 have been stored in the memory core 850 in a form, such as the form illustrated in FIGS. 9C and 9D, the second neighboring 2-bit error information 2b_CORRECT_1 may be required to correct a neighboring 2-bit error. The selector 1071 may perform a selection operation according to an address ADD. Specifically, when the value of a row address included in the address ADD is an even number, the selector 1071 may select the first neighboring 2-bit error information 2b_CORRECT_0. When the value of a row address included in the address ADD is an odd number, the selector 1071 may select the second neighboring 2-bit error information 2b_CORRECT_1.

The error corrector 1073 may correct an error of the data D0′ to D31′ by using the random 1-bit error correction information 1b_CORRECT and neighboring 2-bit error information 2b_CORRECT_SEL that has been selected by the selector 1071. The error corrector 1073 may correct an error by inverting a corresponding bit, when the random 1-bit error correction information 1b_CORRECT indicates that an error is present in any 1 bit of the data D0′ to D31′. For example, when the random 1-bit error correction information 1b_CORRECT indicates that an error is present in the data D23′, the error corrector 1073 may correct the error by inverting the data D23′. Furthermore, when the neighboring 2-bit error information 2b_CORRECT_SEL that has been selected indicates that errors are present in any 2 bits, the error corrector 1073 may correct the errors by inverting the 2 bits. For example, when the neighboring 2-bit error information 2b_CORRECT_SEL that has been selected indicates that errors are present in the data D4′ and D5′, the error corrector 1073 may correct the errors by inverting the 2-bit data D4′ and D5′. The data D0 to D31 that are output by the error corrector 1073 may be data having an error corrected.

In this case, it has been illustrated that the error corrector 1073 corrects a 2-bit error by using the neighboring 2-bit error information 2b_CORRECT_SEL that has been selected by the selector 1071. In another embodiment, the error corrector 1073 may correct a 2-bit error by using both the first and second neighboring 2-bit error information 2b_CORRECT_0 and 2b_CORRECT_1. The reason for this is that there is almost no probability that the first neighboring 2-bit error information 2b_CORRECT_0 and the second neighboring 2-bit error information 2b_CORRECT_1 may be contradictory to each other. For example, if the first neighboring 2-bit error information 2b_CORRECT_0 indicates that errors of the data D0′ and D1′ need to be corrected, the second neighboring 2-bit error information 2b_CORRECT_1 may include information indicating that an error does not need to be corrected.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure. Furthermore, the embodiments may be combined to form additional embodiments.

What is claimed is:

1. A memory comprising:
a memory core;
a syndrome generation circuit configured to generate a syndrome based on data and an error correction code (ECC), which are read from the memory core;
a first decoder configured to generate first error correction information based on a first decoding table and the syndrome;
a second decoder configured to generate second error correction information based on the syndrome and a second decoding table different from the first decoding table; and
an error correction circuit configured to correct an error of the read data based on the first error correction information and the second error correction information.

2. The memory of claim 1, wherein
the first decoding table is prepared with data that are arranged in a first pattern and have been stored in memory cells having a high possibility that errors are to simultaneously occur among the read data, and
wherein the second decoding table is prepared with data that are arranged in a second pattern different from the first pattern and have been stored in memory cells having a high possibility that errors are to simultaneously occur among the read data.

3. The memory of claim 1, wherein the error correction circuit is configured to selectively use one of the first error correction information and the second error correction information according to an address corresponding to the read data.

4. The memory of claim 1, wherein the error correction circuit comprises:
a selector configured to select one of the first error correction information and the second error correction information according to an address corresponding to the read data; and
an error corrector configured to correct the error of the read data based on error correction information selected by the selector.

5. The memory of claim 1, wherein the error correction circuit comprises an error corrector configured to correct an error indicated by the first error correction information in the read data and an error indicated by the second error correction information in the read data.

6. The memory of claim 1, wherein the syndrome generation circuit comprises:
a check matrix operation circuit configured to perform an operation on a check matrix and the read data; and
a syndrome operation circuit configured to perform an exclusive OR operation on results of the operation of the check matrix operation circuit and the ECC read from the memory core to generate the syndrome.

7. The memory of claim 6, wherein the check matrix operation circuit is configured to perform an operation on the check matrix and the write data during a write operation to generate the ECC to be stored in the memory core along with write data.

8. The memory of claim 2, wherein the errors that are to simultaneously occur are due to a storage node bridge failure.

9. A memory comprising:
a memory core;
a syndrome generation circuit configured to generate a syndrome based on data and an error correction code (ECC), which are read from the memory core;
a single error decoder configured to generate random 1-bit error correction information based on the syndrome and a decoding table identical with a check matrix that is used to generate the syndrome;
a first neighboring 2-bit error decoder configured to generate first neighboring 2-bit error correction information based on the first decoding table and the syndrome;
a second neighboring 2-bit error decoder configured to generate second neighboring 2-bit error correction information based on the syndrome and a second decoding table different from the first decoding table; and
an error correction circuit configured to correct a random 1-bit error of the read data based on the random 1-bit error correction information and to correct a neighboring 2-bit error of the read data based on the first neighboring 2-bit error correction information and the second neighboring 2-bit error correction information.

10. The memory of claim 9, wherein
the first decoding table is prepared with data that are arranged in a first pattern and have been stored in memory cells having a high possibility that errors are to simultaneously occur among the read data, and
wherein the second decoding table is prepared with data that are arranged in a second pattern different from the first pattern and have been stored in memory cells having a high possibility that errors are to simultaneously occur among the read data.

11. The memory of claim 10, wherein the first decoding table and the second decoding table are decoding tables each obtained by abbreviating columns of a decoding table identical with a check matrix that is used to generate the syndrome to 2:1.

12. The memory of claim 9, wherein the error correction circuit is configured to:
correct the random 1-bit error of the read data based on the random 1-bit error correction information;
select one of the first neighboring 2-bit error correction information and the second neighboring 2-bit error correction information according to an address corresponding to the read data; and
correct a neighboring 2-bit error of the read data based on the selected error correction information.

13. The memory of claim 9, wherein the error correction circuit comprises:
a selector configured to select one of the first neighboring 2-bit error correction information and the second neighboring 2-bit error correction information according to an address corresponding to the read data; and
an error corrector configured to correct a random 1-bit error of the read data based on the random 1-bit error correction information and to correct a neighboring 2-bit error of the read data based on the error correction information selected by the selector.

14. The memory of claim 9, wherein the error correction circuit comprises an error corrector configured to:
correct a random 1-bit error of the read data based on the random 1-bit error correction information; and
correct a neighboring 2-bit error of the read data based on the first neighboring 2-bit error correction information and the second neighboring 2-bit error correction information.

15. The memory of claim 9, wherein the syndrome generation circuit comprises:
a check matrix operation circuit configured to perform an operation on the check matrix and the read data; and
a syndrome operation circuit configured to perform an exclusive OR operation on results of the operation of the check matrix operation circuit and the ECC that is read from the memory core to generate the syndrome.

16. The memory of claim 15, wherein the check matrix operation circuit is configured to perform an operation on the check matrix and the write data during a write operation to generates the ECC to be stored in the memory core along with write data.

17. The memory of claim 10, wherein the errors that are to simultaneously occur are due to a storage node bridge failure.
